(19) United States
(12) Patent Application Publication
(10) Pub. No.: US 2024/0242938 A1
(43) Pub. Date: Jul. 18, 2024

(54) ETCHING DEVICE AND ETCHING METHOD

(71) Applicant: ULVAC, INC., Chigasaki-shi (JP)

(72) Inventors: Kazuhiko Tonari, Chigasaki-shi (JP); Hiroaki Inoue, Chigasaki-shi (JP); Youhei Ono, Chigasaki-shi (JP); Jun-chang Park, Pyeongtaek-Si (KR); Won-yeong Kim, Pyeongtaek-Si (KR)

(21) Appl. No.: 18/408,369

(22) Filed: Jan. 9, 2024

(30) Foreign Application Priority Data
Jan. 13, 2023 (JP) 2023-003537

(51) Int. Cl. H01J 37/32; H01L 21/311; H01L 21/67

(52) U.S. Cl. CPC H01J 37/3244; H01L 21/31116; H01L 21/67017; H01J 37/32192; H01J 2237/334

(57) ABSTRACT

An etching device includes a discharge tube irradiated with microwaves and a gas supplying unit configured to supply a gas mixture to the discharge tube. The etching device is configured to generate plasma of the gas mixture in the discharge tube and etch a silicon-containing film on a substrate by delivering the plasma and a fluorine-containing gas to the silicon-containing film. The gas mixture contains hydrogen atoms, nitrogen atoms, and oxygen atoms. The discharge tube is formed from a main component of aluminum oxide.

### CROSS-REFERENCE TO RELATED APPLICATION

This application claims the benefit of priority under 35 U.S.C. § 119 to Japanese Patent Application No. 2023-003537, filed on Jan. 13, 2023, which is incorporated by reference herein in its entirety.

### BACKGROUND

### 1. Field

The following description relates to an etching device and an etching method.

### 2. Description of Related Art

One example of an etching device that removes a natural oxide film from a silicon substrate uses radicals contained in plasma, which is generated by the emission of microwaves, as an etchant that reacts with the natural oxide film. The etching device heats the silicon substrate to vaporize the complexes formed from the etchant and the natural oxide film (refer to Japanese Laid-Open Patent Publication No. 2022-59358).

### SUMMARY

The plasma used to produce the etchant includes hydrogen atoms and nitrogen atoms such as hydrogen radicals and hydronitrogen radicals. The hydrogen atoms act to reduce the natural oxide film, and nitrogen atoms act to extend the lifespan of the radicals. The plasma including hydrogen atoms and nitrogen atoms is generated by irradiating a quartz tube, which is supplied with hydrogen gas and ammonia gas, with microwaves. The quartz tube that continues to generate the plasma including hydrogen atoms and nitrogen atoms, however, may become nitrogenized when used over a long period of time. This will lower the etching rate of the natural oxide film.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, an etching device includes a discharge tube irradiated with microwaves and a gas supplying unit configured to supply a gas mixture to the discharge tube. The etching device is configured to generate plasma of the gas mixture in the discharge tube and etch a silicon-containing film on a substrate by delivering the plasma and a fluorine-containing gas to the silicon-containing film. The gas mixture contains hydrogen atoms, nitrogen atoms, and oxygen atoms. The discharge tube is formed from a main component of aluminum oxide.

In another general aspect, an etching method includes supplying a gas mixture to a discharge tube, generating plasma of the gas mixture in the discharge tube by irradiating the discharge tube with microwaves, and etching a silicon-containing film on a substrate by delivering the plasma and a fluorine-containing gas to the silicon-containing film. The gas mixture contains hydrogen atoms, nitrogen atoms, and oxygen atoms. The discharge tube is formed from a main component of aluminum oxide.

In each of the above aspects, the discharge tube, which generates hydrogen radicals and hydronitrogen radicals, is formed from a main component of aluminum oxide. Thus, in contrast with when the discharge tube is formed from a silicon oxide such as quartz nitrogenization of the discharge tube will be mitigated. Consequently, the etching rate will not be affected by nitrogenization of the discharge tube. Dangling bonds in the surface of the aluminum oxide prompts the deactivation of the hydrogen radicals. In this regard, the gas mixture contains oxygen atoms. Thus, oxygen radicals limit the formation of dangling bonds in the surface of the aluminum oxide. This allows the etching rate of the silicon-containing film to be increased.

Other features and aspects will be apparent from the following detailed description, the drawings, and the claims.

### BRIEF DESCRIPTION OF THE DRAWINGS

FIG. 1 is a diagram illustrating the configuration of the etching device.

FIG. 2 is a diagram illustrating the configuration of a processing chamber.

FIG. 3 is a graph illustrating the relationship of the oxygen gas concentration and the etching amount.

FIG. 4 is a graph illustrating the relationship of the oxygen gas concentration and the etching amount.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

In this specification, “at least one of A and B” should be understood to mean “only A, only B, or both A and B.”

### Etching Device

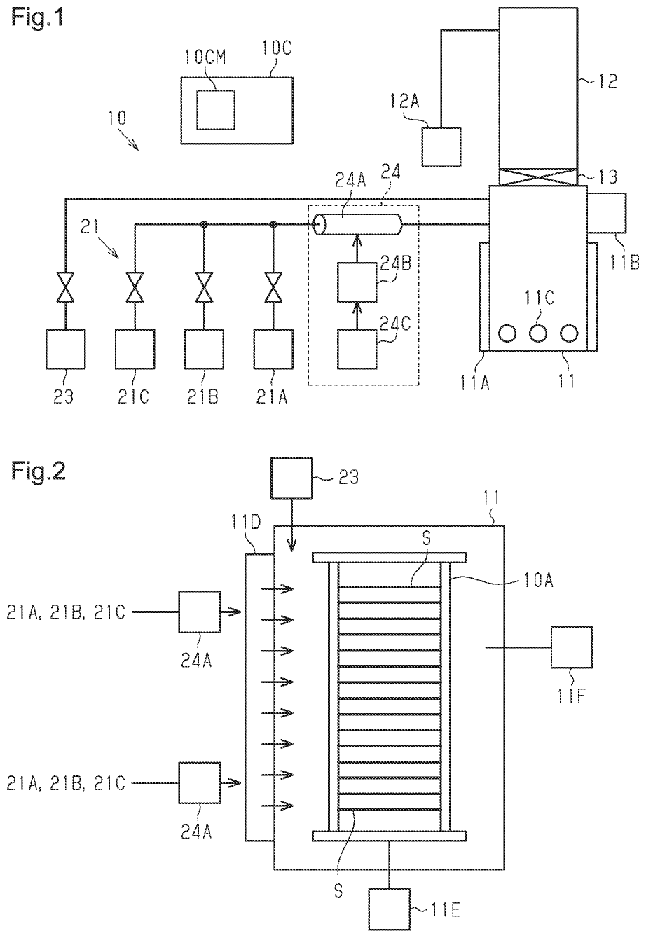

As shown in FIG. 1, an etching device 10 includes an etching chamber 11, a load lock chamber 12, and a gate valve 13. The etching device 10 includes a gas mixture supplying unit 21, a fluorine-containing gas supplying unit 23, and a plasma supplying unit 24. The etching device 10 includes a controller 10C.

The etching chamber 11 includes an accommodation space where a substrate S (refer to FIG. 2) is accommodated. The etching chamber 11 etches a silicon oxide film on the substrate S in the accommodation space. The load lock chamber 12 loads a pre-etched substrate S from an external environment into the etching chamber 11. The load lock chamber 12 then unloads the etched substrate S out of the etching chamber 11 to the external environment.

The gate valve 13 is located between the etching chamber 11 and the load lock chamber 12. The gate valve 13 opens and connects the etching chamber 11 and the load lock chamber 12. The gate valve 13 closes and separates the etching chamber 11 from the load lock chamber 12.

The load lock chamber 12 is connected to a coolant gas supplying unit 12A. The coolant gas supplying unit 12A supplies coolant gas to the load lock chamber 12. The coolant gas is an inert gas used to cool the etched substrate S.

The etching chamber 11 includes a first heater 11A, a vent 11B, and a second heater 11C. The first heater 111A heats the etching chamber 11. The vent 11B reduces the pressure of the etching chamber 11 to a predetermined pressure. The second heater 11C heats the substrate S that is accommodated in the etching chamber 11.

The etching chamber 11 is connected to the fluorine-containing gas supplying unit 23 and the plasma supplying unit 24. The fluorine-containing gas supplying unit 23 supplies fluorine-containing gas to the accommodation space where the substrate S is accommodated in the etching chamber 11. One example of a fluorine-containing gas is nitrogen trifluoride gas. The plasma supplying unit 24 supplies plasma to the accommodation space of the etching chamber 11 where the substrate S is accommodated.

The plasma supplying unit 24 includes a discharge tube 24A, a waveguide 24B, and a microwave source 24C. The microwave source 24C emits microwaves through the waveguide 24B to the discharge tube 24A. The discharge tube 24A is connected to the gas mixture supplying unit 21. The discharge tube 24A is formed from a main component of aluminum oxide. The discharge tube 24A may be a sapphire tube formed from sapphire or an alumina tube formed from sintered alumina. Sintered alumina is a sintered material synthesized from a precursor of aluminum oxide powder or ammonium dawsonite and may contain aluminum oxynitride oxide or a metal element other than aluminum such as yttrium. The purity of aluminum oxide with respect to the total mass of the discharge tube 24A is greater than 50 mass %, preferably, 90 mass % or greater, and further preferably, 99 mass % or greater.

The gas mixture supplying unit 21 supplies the discharge tube 24A with a gas mixture containing hydrogen atoms, nitrogen atoms, and oxygen atoms. The gas mixture supplying unit 21 includes a nitrogen gas supplying unit 21A, an ammonia gas supplying unit 21B, and an oxygen gas supplying unit 21C. The nitrogen gas supplying unit 21A supplies nitrogen gas to the discharge tube 24A. The ammonia gas supplying unit 21B supplies ammonia gas to the discharge tube 24A. The oxygen gas supplying unit 21C supplies oxygen gas to the discharge tube 24A.

The plasma supplying unit 24 irradiates the gas mixture in the discharge tube 24A with microwaves to generate plasma in the discharge tube 24A. The plasma supplying unit 24 supplies the plasma generated in the discharge tube 24A to the accommodation space in the etching chamber 11 where the substrate S is accommodated. The plasma supplied to the etching chamber 11 includes hydrogen radicals, nitrogen radicals, and hydronitrogen radicals.

The controller 10C includes a memory 10CM. The memory 10CM stores processing conditions for etching silicon oxide films. The processing conditions include the pressure of the etching chamber 11, the temperature of the substrate S, the flow rate of each gas, and the output of the microwave source 24C. The controller 10C controls and drives the first heater 11A, the vent 11B, the second heater 11C, the gas mixture supplying unit 21, the fluorine-containing gas supplying unit 23, and the plasma supplying unit 24 so that the etching conditions match the processing conditions.

### Etching Chamber 11

As shown in FIG. 2, the etching chamber 11 accommodates a support 10A. The support 10A supports a plurality of substrates S. The substrates S supported by the support 10A are arranged one over another with a gap extending between adjacent ones of the substrates S. Each substrate S includes a silicon oxide film. One example of the substrate S is a disc-shaped silicon substrate.

The etching chamber 11 includes a shower head 11D. The shower head 11D is connected to the discharge tube 24A. Any number of discharge tubes 24A may be connected to the shower head 11D. FIG. 2 shows an example in which two discharge tubes 24A are connected to the shower head 11D. The shower head 11D includes nozzles. The nozzles of the shower head 11D are arranged one over another in the direction in which the substrates S are arranged. The plasma supplied from the discharge tubes 24A is expelled from the nozzles of the shower head 11D toward the substrates S.

The etching chamber 11 includes a rotor 11E. The rotor 11E rotates the support 10A in the circumferential direction of the substrate S. The rotor 11E disperses the plasma expelled from the shower head 11D toward the substrates S and the fluorine-containing gas delivered from the fluorine-containing gas supplying unit 23 toward the substrate S in the circumferential direction of the substrate S.

The etching chamber 11 includes a thermometer 11F. The thermometer 11F measures the temperature inside the etching chamber 11 as the temperature of the substrate S. The thermometer 11F is connected to the controller 10C. The temperature measured by the thermometer 11F is input to the controller 10C. The controller 10C controls and drives the first heater 11A and the second heater 11C based on the measurement of the thermometer 11F.

### Etching Method

The etching method executed by the etching device 10 includes supplying the gas mixture to the discharge tube 24A, generating plasma of the gas mixture in the discharge tube 24A by irradiating the discharge tube 24A with microwaves, and etching the silicon oxide film by delivering the fluorine-containing gas and the plasma of the gas mixture to the silicon oxide film.

Prior to execution of the etching method, the etching device 10 arranges the support 10A in the load lock chamber 12 and places the substrates S in the support 10A. Then, the etching device 10 opens the gate valve 13 and loads the support 10A supporting the substrates S from the load lock chamber 12 into the etching chamber 11. The etching device 10 then closes the gate valve 13 and vents the etching chamber 11.

When executing the etching method, the etching device 10 heats the substrates S with the first heater 11A and the second heater 11C and rotates the substrates S with the rotor 11E. Then, in accordance with the processing conditions, the etching device 10 supplies the gas mixture from the gas mixture supplying unit 21 and supplies the fluorine-containing gas from the fluorine-containing gas supplying unit 23. Further, in accordance with the processing conditions, the etching device 10 outputs microwaves from the microwave source 24C and supplies the plasma of the gas mixture from the discharge tubes 24A to the substrates S. This etches the silicon oxide film from each substrate S.

When increasing the etching rate, the etching device 10 may set the flow rate of oxygen gas so that the oxygen gas concentration in the accommodation space of the etching chamber 11 where the substrates S are accommodated is greater than or equal to 10 ppm and less than or equal to 1000 ppm. The oxygen gas concentration is the concentration of oxygen molecules obtained by converting the amount of oxygen atoms in the accommodation space of the etching chamber 11 where the substrates S are accommodated into an amount of the oxygen molecules.

### Stability Evaluation

A test was conducted to evaluate the etching rate stability of a etching device 10 of a comparative example using a quartz tube as the discharge tube 24A and an etching device 10 of an example using a sapphire tube as the discharge tube 24A.

The stability evaluation test was conducted a number of times by repeating etching under the processing conditions described below. The stability evaluation test was conducted each time etching was performed by measuring the etching amount of the silicon oxide film and calculating the etching rate from the etching amount. The effect of the etching rate on the usage period of the discharge tube 24A was evaluated. The usage period of the discharge tube 24A corresponds to the accumulated etching time.

### Processing Conditions

Nitrogen gas flowrate: 4000 sccm
Ammonia gas flowrate: 1000 sccm
Oxygen gas flowrate: 1 sccm
Nitrogen trifluoride gas flowrate: 4000 sccm
Temperature of substrates S: 25° C.
Microwave source power: 3000 W
Volume of etching chamber 11: 70 L
Pressure of etching chamber 11: 200 Pa
Etching time: 1000 seconds

During the stability evaluation test, in the etching device 10 of the comparative example, the etching rate decreased continuously as the usage period of the discharge tube 24A increased. The decrease in the etching rate per unit usage time was substantially constant from when etching was initiated. Thus, when the discharge tube 24A was a quartz tube, nitrogenization resulted in continuous deterioration of the discharge tube 24A that caused the etching rate to decrease continuously from when usage of the discharge tube 24A began.

In the etching device 10 of the example, the etching rate did not decrease and remained substantially the same over the same usage period as the etching device 10 of the comparative example. Thus, as long as the discharge tube 24A is a sapphire tube, the etching rate will not start to decrease from when usage of the discharge tube 24A begins. Further, as long as the discharge tube 24A is a sapphire tube, the period during which the etching rate is stable will be prolonged. In other words, as long as the discharge tube 24A is a sapphire tube, the initial stability of the etching device 10 will be increased, and the lifespan of the discharge tube 24A will be prolonged.

### Oxygen Gas Concentration Evaluation

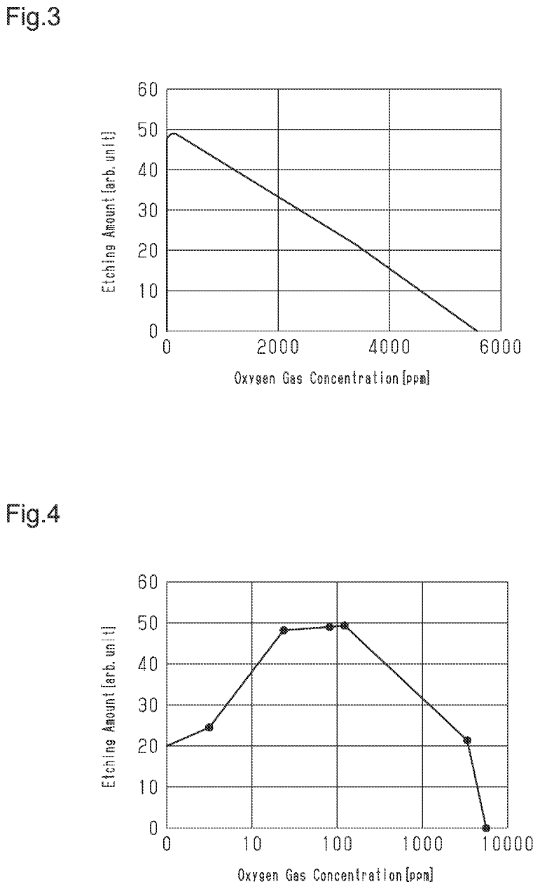

With the etching device 10 of the example, the oxygen gas concentration under the above processing conditions was varied in the range from 0 ppm to 6000 ppm, and the etching amount of the silicon oxide film with respect to the oxygen gas concentration was measured. FIG. 3 shows the measurement result of the etching amount per unit time with respect to the oxygen gas concentration. FIG. 4 is a graph applying a logarithmic axis to the oxygen gas concentration axis of FIG. 3.

As shown in FIGS. 3 and 4, as the oxygen gas concentration increases from 0 ppm to 100 ppm, the etching amount increases rapidly. After the oxygen gas concentration at which the etching amount peaks, the etching amount gradually decreases as the oxygen gas concentration increases from 100 ppm to 6000 ppm. In contrast with when the oxygen gas concentration is 0 ppm, the etching amount will be sufficient when the oxygen gas concentration is in the range of 10 ppm or greater and 1000 ppm or less. In particular, when the oxygen gas concentration is in the range of 50 ppm or greater and 500 ppm or less, the etching amount will be large and relatively uniform.

The above embodiment has the advantages described below.

(1) The discharge tube 24A is formed from a main component of aluminum oxide. Thus, in contrast with when the discharge tube 24A is formed from a silicon oxide such as quartz, nitrogenization of the discharge tube 24A will be mitigated. This limits decreases in the etching rate that would be caused by nitrogenization of the discharge tube 24A.

(2) The gas mixture contains oxygen atoms. This limits the formation of dangling bonds in the surface of the aluminum oxide with oxygen radicals. Thus, even though the discharge tube 24A is formed from the main component of aluminum oxide, the deactivation of hydrogen radicals that would be caused by dangling bonds is limited. This allows the etching rate of the silicon oxide film to be increased.

(3) When the discharge tube 24A is formed from sapphire, nitrogenization of the discharge tube 24A and the formation of dangling bonds in the surface of the discharge tube 24A will be further limited.

(4) When the oxygen gas concentration is 10 ppm or greater and 1000 ppm or less, the oxygen atoms will act to further increase the etching rate.

(5) The gas mixture includes nitrogen gas, ammonia gas, and oxygen gas. The oxygen atoms effectively increase the etching rate.

The above embodiment may be modified as described below.

### Etching Chamber 11

The first heater 11A or the second heater 11C may be omitted from the etching chamber 11.

The etching chamber 11 may be connected to an inert gas supplying unit. The inert gas supplying unit supplies the etching chamber 11 with an inert gas, such as nitrogen gas or argon gas, to heat the substrates S.

The etching chamber 11 may be changed to a single-substrate type that etches one substrate S at a time.

### Silicon-Containing Film

The silicon oxide film that is subject to etching may be changed to a silicon-containing film such as a polysilicon film or an amorphous silicon film.

### Gas

The fluorine-containing gas may be a hydrogen fluoride gas, a carbon tetrafluoride gas, or a silicon tetrafluoride gas. The fluorine-containing gas forms an etchant when the plasma generated from the gas mixture reacts with the silicon-containing film.

The gas mixture contains hydrogen atoms, nitrogen atoms, and oxygen atoms. The gas mixture may be a combination of two or more gases selected from a group consisting of ammonia gas, hydrogen gas, nitrogen gas, dinitrogen monoxide gas, nitrogen dioxide gas, oxygen gas, ozone gas, and water vapor gas. The gas mixture may be, for example, a combination of hydrogen gas, nitrogen gas, and oxygen gas, a combination of hydrogen gas and dinitrogen monoxide, or a combination of ammonia gas and oxygen gas. The gas mixture may further contain a noble gas such as argon gas or helium gas. The gas mixture may contain a mixture of dinitrogen monoxide gas and nitrogen dioxide gas as a source for supplying nitrogen atoms and oxygen atoms.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

### Examples

Example 1 is an etching device, comprising: a discharge tube irradiated with microwaves; and a gas supplying unit configured to supply a gas mixture to the discharge tube, wherein the etching device is configured to generate plasma of the gas mixture in the discharge tube and etch a silicon-containing film on a substrate by delivering the plasma and a fluorine-containing gas to the silicon-containing film, wherein the gas mixture contains hydrogen atoms, nitrogen atoms, and oxygen atoms, and wherein the discharge tube is formed from a main component of aluminum oxide.

In Example 2, the subject matter of Example 1 optionally includes subject matter wherein the discharge tube is formed from sapphire.

In Example 3, the subject matter of any one or more of Examples 1-2 optionally includes subject matter, wherein the oxygen gas concentration in an accommodation space where the substrate is accommodated is greater than or equal to 10 ppm and less than or equal to 1000 ppm, wherein the oxygen gas concentration is a concentration of oxygen molecules in the accommodation space when converting an amount of the oxygen atoms in the accommodation space into an amount of the oxygen molecules.

In Example 4, the subject matter of Example 3 optionally includes subject matter wherein the gas mixture contains nitrogen gas, ammonia gas, and oxygen gas.

Example 5 is an etching method, comprising: supplying a gas mixture to a discharge tube: generating plasma of the gas mixture in the discharge tube by irradiating the discharge tube with microwaves; and etching a silicon-containing film on a substrate by delivering the plasma and a fluorine-containing gas to the silicon-containing film, wherein the gas mixture contains hydrogen atoms, nitrogen atoms, and oxygen atoms, and wherein the discharge tube is formed from a main component of aluminum oxide.

In Example 6, the subject matter of Example 5 optionally includes subject matter wherein the discharge tube is formed from sapphire.

In Example 7, the subject matter of any one or more of Examples 5-6 optionally includes subject wherein the oxygen gas concentration in an accommodation space where the substrate is accommodated is greater than or equal to 10 ppm and less than or equal to 1000 ppm, wherein the oxygen gas concentration is a concentration of oxygen molecules in the accommodation space when converting an amount of the oxygen atoms in the accommodation space into an amount of the oxygen molecules.

In Example 8, the subject matter of any one or more of Examples 5-7 optionally includes subject matter wherein the gas mixture contains nitrogen gas, ammonia gas, and oxygen gas.

What is claimed is:

1. An etching device, comprising:
a discharge tube irradiated with microwaves, and
a gas supplying unit configured to supply a gas mixture to the discharge tube, wherein the etching device is configured to generate plasma of the gas mixture in the discharge tube and etch a silicon-containing film on a substrate by delivering the plasma and a fluorine-containing gas to the silicon-containing film, wherein the gas mixture contains hydrogen atoms, nitrogen atoms, and oxygen atoms, and wherein the discharge tube is formed from a main component of aluminum oxide.

2. The etching device of claim 1, wherein the discharge tube is formed from sapphire.

3. The etching device according to claim 1, wherein an oxygen gas concentration in an accommodation space where the substrate is accommodated is greater than or equal to 10 ppm and less than or equal to 1000 ppm, wherein the oxygen gas concentration is a concentration of oxygen molecules in the accommodation space when converting an amount of the oxygen atoms in the accommodation space into an amount of the oxygen molecules.

4. The etching device according to claim 3, wherein the gas mixture contains nitrogen gas, ammonia gas, and oxygen gas.

5. An etching method, comprising:
supplying a gas mixture to a discharge tube;
generating plasma of the gas mixture in the discharge tube by irradiating the discharge tube with microwaves; and
etching a silicon-containing film on a substrate by delivering the plasma and a fluorine-containing gas to the silicon-containing film, wherein the gas mixture contains hydrogen atoms, nitrogen atoms, and oxygen atoms, and wherein the discharge tube is formed from a main component of aluminum oxide.
